(19) United States
(12) Patent Application Publication
(10) Pub. No.: US 2008/0308951 A1
(43) Pub. Date: Dec. 18, 2008

(54) Semiconductor package and fabrication method thereof

(75) Inventors: Yuan-Chun Li, Taichung (TW); Chien-Ping Huang, Taichung (TW); Lien-Chen Chiang, Taichung Hsien (TW); We-Horng Shyu, Taichung (TW); Chih-Shiang Wang, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/157,836

(22) Filed: Jun. 13, 2008

(30) Foreign Application Priority Data
Jun. 13, 2007 (TW) 096121281

(51) Int. Cl. H01L 21/50; H01L 23/00

(52) U.S. Cl. 257/778; 438/108; 257/E21.499; 257/E23.001

(57) ABSTRACT

A semiconductor package and a fabrication method thereof are disclosed. The fabrication method includes providing a carrier board; forming a plurality of metal bumps on the carrier board; covering on the carrier board a resist layer having openings for exposure of the metal bumps, the openings being smaller than the metal bumps in width such that a metal layer is formed in the openings, the metal layer having extension circuits and extension pads and bonding pads formed on respective ends of the extension circuits; removing the resist layer; electrically connecting at least one semiconductor chip to the bonding pads; forming an encapsulant on the carrier board to encapsulate the semiconductor chip; and removing the carrier board and the metal bumps to expose the metal layer. Therefore, the extension pads of the exposed metal layer can be electrically connected to an external device through a conductive material in subsequent processes, and the extension circuits can be disposed flexibly in accordance with the degree of integration of the chip, so as to reduce the electrical connection path between the chip and the extension circuits.

### FIELD OF THE INVENTION

The present invention relates to a semiconductor package and a fabrication method thereof, and more particularly, to a carrier-free semiconductor package and a fabrication method thereof.

### BACKGROUND OF THE INVENTION

There are various types of semiconductor packages that use lead frames as chip carriers. As for a QFN (Quad Flat Non-leaded) semiconductor package, there is no outer lead as can be found in a traditional QFP (Quad Flat Package) semiconductor package for external electrical connection. As a result, the size of a QFN semiconductor package can be reduced.

However, sometimes, the overall height of the QFN package cannot be further reduced due to thickness of the encapsulant. Thus, in order to meet the need for more compact and lighter semiconductor products, a carrier-free semiconductor package is proposed, which becomes much lighter and thinner by reducing the thickness of the lead frame.

Referring to FIG. 1, a carrier-free semiconductor package disclosed by U.S. Pat. No. 5,830,800 is shown. The carrier-free semiconductor package is provided by first forming a plurality of electroplated pads 12 on a copper plate (not shown); then attaching a chip 13 on the copper plate, and electrically connecting the chip 13 and the electroplated pads 12 via bonding wires 14; performing an encapsulation molding process to form an encapsulant 15; etching to remove the copper plate so as to expose the electroplated pads 12; forming a solder-resist layer 11 to define locations of the electroplated pads 12, so that solder balls 16 can be implanted on the electroplated pads 12. Related techniques can be found by referring to U.S. Pat. Nos. 6,770,959, 6,989,294, 6,933,594 and 6,872,661.

The number of the above-mentioned electroplated pads approximately corresponds to the number of electrically connecting pads on the active surface of the chip such that the electrically connecting pads can be respectively connected to the corresponding electroplated pads. However, if a highly integrated chip is used, i.e. the number or density of electrically connecting pads is large, more electroplated pads have to be provided. This increases the distance between the chip and the electroplated pads and the arc length of the bonding wires. Too long wires increase the difficulty of wiring bonding operations. Moreover, during molding of the encapsulant, sweep or shift phenomenon tends to occur more easily to long bonding wires as a result of resin mold flow. Swept or shifted wires may come into contact with each other and result in a short circuit, thereby degrading the quality of electrical connection. Furthermore, if the distance between the electroplated pads and the chip is too far, wires cannot be bonded.

In view of this, U.S. Pat. No. 6,884,652 proposes a wire redistribution layer that enables the electroplated pads to be extended near the chip, thus reducing wire length or wire crossing. The method of fabrication is shown in FIGS. 2A to 2E. A dielectric layer 21 is first applied on a copper plate 20. A plurality of openings 210 is formed at predefined locations of the dielectric layer 21, into which a solder material 22 is coated by electroplating (as shown in FIG. 2A). A first thin copper layer 23 is deposited on the dielectric layer 21 and the solder material 22 by electroless plating or sputtering (as shown in FIG. 2B). A second copper layer 24 is electroplated on the first thin copper layer 23, and the first thin copper layer 23 and the second copper layer 24 are patterned to form a plurality of conductive traces, such that each trace has a terminal 241. A metal layer 25 is further coated on the terminals 241 of the conductive traces 24 by electroplating (as shown in FIG. 2C). At least a chip 26 is mounted on predefined location of the conductive traces, with a plurality of bonding wires 27 electrically connecting the chip and the terminals coated with the metal layer 25, and an encapsulant 28 is formed to encapsulate the chip 26 and the bonding wires 27 (as shown in FIG. 2D). Then, the copper plate 20 is removed by etching to expose the dielectric layer 21 and the solder material 22 (as shown in FIG. 2E).

However, this method requires the use of the dielectric layer to define the terminals for external connection of the chip, and forming of the wire redistribution layer (i.e. conductive traces) by numerous processes such as sputtering, electroplating and exposure, developing, and etching, which is expensive and complicated.

Furthermore, the traditional carrier-free semiconductor package fails to provide ground and power rings. The main reason is that the bonding pads for external electrical connection and ground and power rings in such a semiconductor package are exposed from the encapsulant. Thus, when the package is electrically connected to external devices through the surface mount technology (SMT), neighboring ground and power rings may be easily shorted. Since ground and power rings cannot be disposed in such a carrier-free semiconductor package, passive elements such as capacitors also cannot be disposed thereon. As a result, the electrical quality of such a carrier-free semiconductor package cannot be effectively improved.

Therefore, there is a need for a carrier-free semiconductor package and a fabrication thereof, which increases the number of electrical terminals, eliminates wire crossing, and reduces the length of bonding wires as well as cost and complication related to the wire redistribution method, such as use of dielectric layer, sputtering, electroplating, exposure, developing and etching. Additionally, ground and power rings and passive elements can be disposed in this carrier-free semiconductor package, thereby improving the electrical quality thereof.

### SUMMARY OF THE INVENTION

In the light of the forgoing drawbacks, an objective of the present invention is to provide a carrier-free semiconductor package and a fabrication method thereof.

Another objective of the present invention is to provide a carrier-free semiconductor package and a fabrication method thereof that reduces the length and crossing of bonding wires connected between the semiconductor chip and the package while increasing the number of electrical terminals of the package.

Still another objective of the present invention is to provide a carrier-free semiconductor package and a fabrication method thereof that reduces cost and complication related to the conventional wire redistribution method, such as use of dielectric layer to define terminals, sputtering, electroplating, exposure, developing and etching.

Yet another objective of the present invention is to provide a carrier-free semiconductor package and a fabrication method thereof that allows the provision of ground and power rings and passive elements therein to improve electrical quality of the package and prevent short circuit.

In accordance with the above and other objectives, the present invention discloses a fabrication method of a semiconductor package, comprising: providing a carrier board with a plurality of metal bumps formed thereon; providing a resist layer on the carrier board, wherein the resist layer has openings to expose the metal bumps; forming a metal layer in the openings of the resist layer, wherein the metal layer comprises extension circuits, and extension pads and bonding pads located on respective ends of the extension circuits; removing the resist layer; electrically connecting at least one semiconductor chip to the bonding pads; forming an encapsulant on the carrier board to enclose the semiconductor chip; and removing the carrier board and the metal bumps to form a plurality of grooves on a surface of the encapsulant for exposing the metal layer. Subsequently, the exposed extension pads of the metal layer can be electrically connected to an external device through a conductive material.

The method of forming the metal bumps and the metal layer comprises: providing the carrier board made of metal, covering the carrier board with a first resist layer, and forming a plurality of first openings in the first resist layer; forming the metal bumps in the first openings by electroplating; removing the first resist layer; providing a second resist layer on the carrier board, wherein the second resist layer has second openings for exposing the metal bumps and portions of the carrier board, and the second openings are slightly smaller than the metal bumps in width; forming the metal layer in the second openings by electroplating; and removing the second resist layer.

Furthermore, the metal bumps can be formed at positions where predefined ground and power circuits are to be formed, such that the ground and power circuits can be formed on the metal bumps for electrically connecting the semiconductor chip to ground and power circuits. Moreover, passive elements such as capacitors can be disposed on the ground and power circuits. Thereafter, an encapsulant can be formed to enclose the chip, and then the carrier board and the metal bumps are removed, such that the ground and power circuits are located within the grooves and exposed from the encapsulant. The grooves are subsequently filled with an insulating layer to protect the exposed ground and power circuits from short circuit.

Through the above method, the present invention further discloses a semiconductor package, comprising: an encapsulant formed with a plurality of grooves on a surface thereof; extension circuits formed in the grooves, wherein bonding pads are disposed on one end of the extension circuits and extension pads are disposed on the other end thereof; and a semiconductor chip enclosed in the encapsulant and electrically connected to the bonding pads.

Moreover, the semiconductor package further comprises ground and power circuits formed in the grooves of the encapsulant and the grooves are filled with an insulating layer to protect the exposed ground and power circuits.

Therefore, the semiconductor package and the method for fabricating the same of the present invention essentially comprises: forming a plurality of metal bumps on a carrier board; forming a metal layer on the carrier board and the metal bumps, wherein the metal layer has extension circuits, and bonding pads and extension pads disposed on respective ends of the extension circuits; electrically connecting at least one semiconductor chip to the bonding pads; forming an encapsulant on the carrier board to enclose the chip; removing the carrier board and the metal bumps to form a plurality of grooves on the surface of the encapsulant, and the extension circuits are located in the grooves, thereby allowing the extension pads disposed on one end of the extension circuits to be electrically connected to an external device through a conductive material.

As such, the semiconductor package of the present invention is free of a chip carrier, and the extension circuits can be disposed flexibly in accordance with the degree of integration of the chip and in proximity with the chip, thus effectively reducing the electric connection path between the chip and the extension circuits and improving circuit layout and electrical quality of the package. This eliminates problems such as short circuit and challenges in wire bonding associated with overly long bonding wires. Additionally, it reduces cost and complication related to the wire redistribution method, such as use of dielectric layer to define terminals, sputtering, electroplating, exposure, developing and etching.

The present invention may further comprise forming metal bumps at positions where predefined ground and power circuits are to be formed, such that the ground and power circuits can be formed on the metal bumps and electrically connected to the semiconductor chip. Moreover, passive elements such as capacitors can be disposed on the ground and power circuits, thus improving the electrical quality of the package. Thereafter, an encapsulant can be formed to enclose the chip, and the carrier board and the metal bumps are removed to form a plurality of grooves on the surface of the encapsulant, such that the ground and power circuits are located within the grooves and exposed from the encapsulant. The grooves are subsequently filled with an insulating layer to protect the exposed ground and power circuits from short circuit.

### BRIEF DESCRIPTION OF THE DRAWINGS

The present invention can be more fully understood by reading the following detailed description of the preferred embodiments, with reference made to the accompanying drawings, wherein:

FIG. 1 is a schematic diagram depicting a carrier-free semiconductor package disclosed by U.S. Pat. No. 5,830,800.

FIGS. 2A to 2E are schematic diagrams depicting a carrier-free semiconductor package disclosed by U.S. Pat. No. 6,884,652.

FIGS. 3A to 3F are schematic diagrams depicting a semiconductor package and a fabrication method thereof according to a first embodiment of the present invention;

FIG. 3G is a schematic diagram depicting a semiconductor package of the present invention electrically connected to an external device;

FIG. 4 is a schematic diagram depicting a semiconductor package and a fabrication method thereof according to a second embodiment of the present invention;

FIG. 5 is a schematic diagram depicting a semiconductor package and a fabrication method thereof according to a third embodiment of the present invention;

FIGS. 6A to 6C are schematic diagrams depicting a semiconductor package and a fabrication method thereof according to a fourth embodiment of the present invention;

FIGS. 7A to 7F are schematic diagrams depicting a semiconductor package and a fabrication method thereof according to a fifth embodiment of the present invention;

FIGS. 8A and 8B are schematic diagrams depicting a semiconductor package and a fabrication method thereof according to a sixth embodiment of the present invention; and

FIG. 9 is a schematic diagram depicting a semiconductor package and a fabrication method thereof according to a seventh embodiment of the present invention

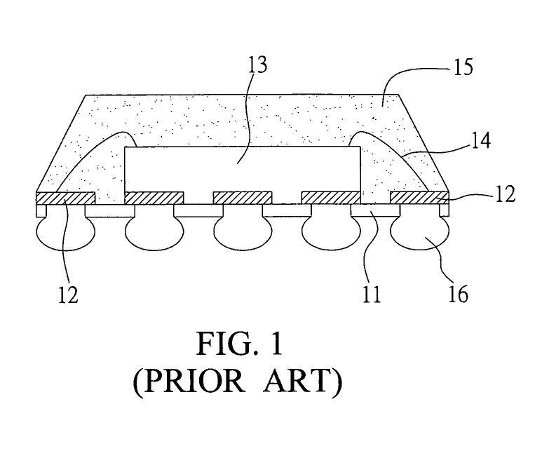

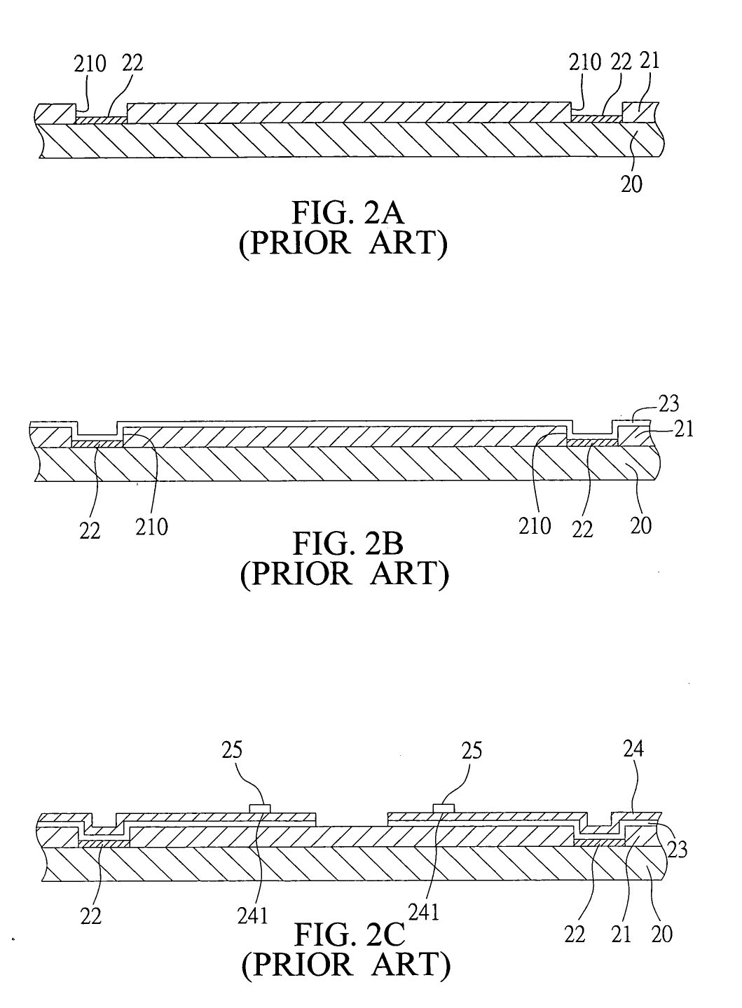

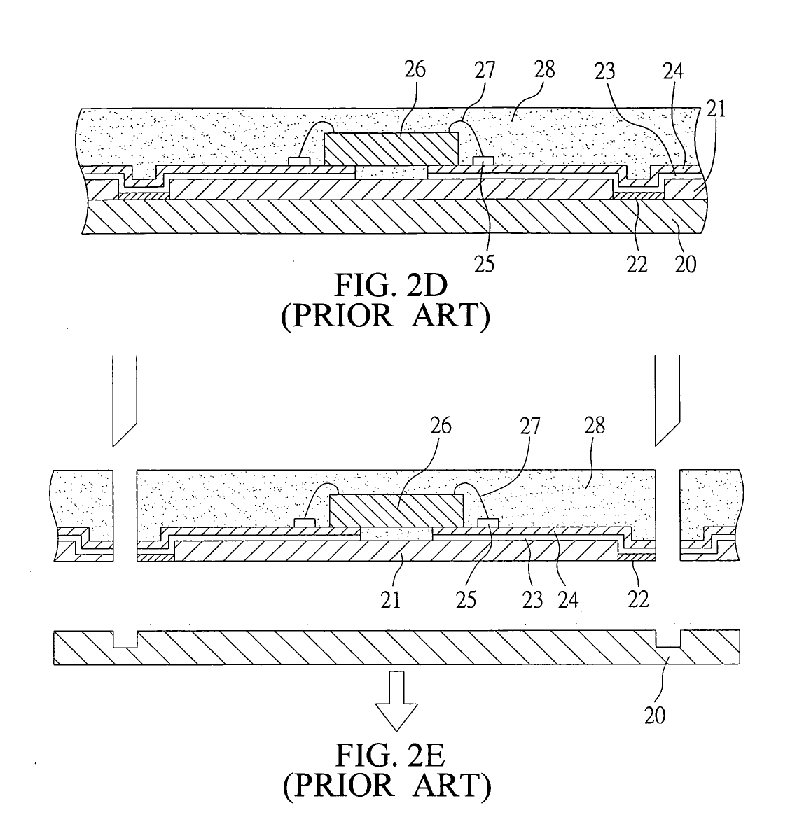

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

### First Embodiment

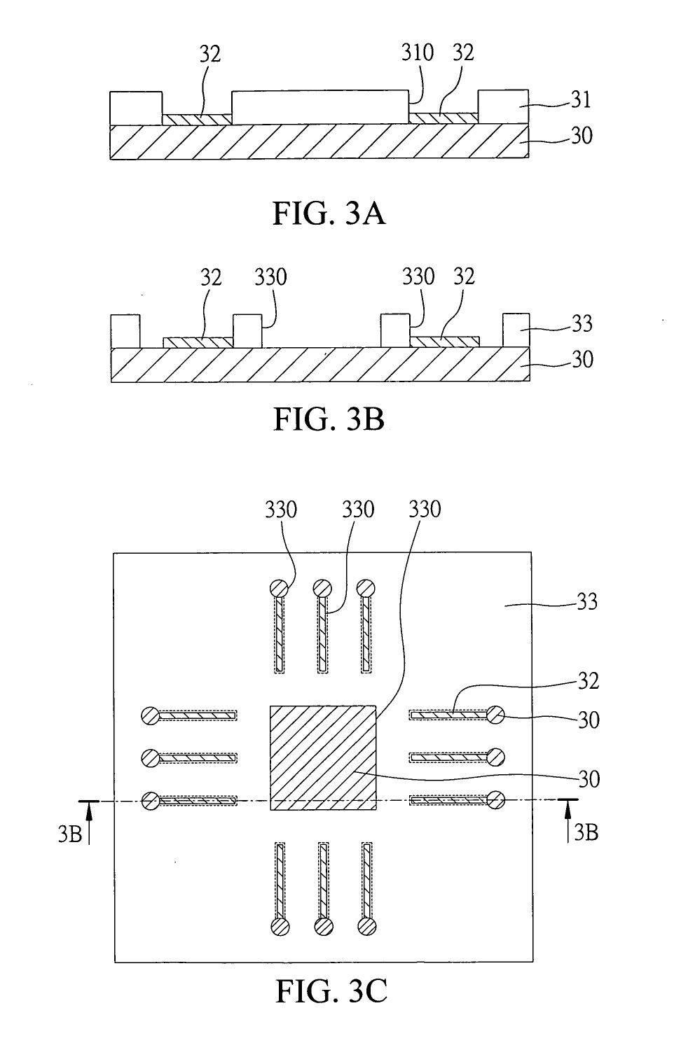

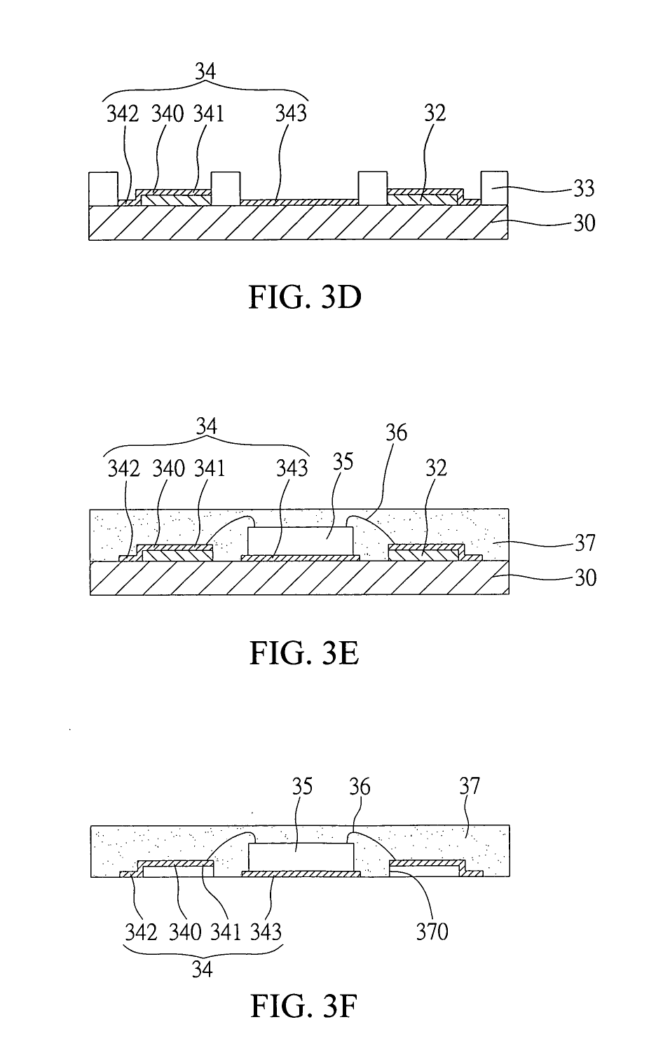

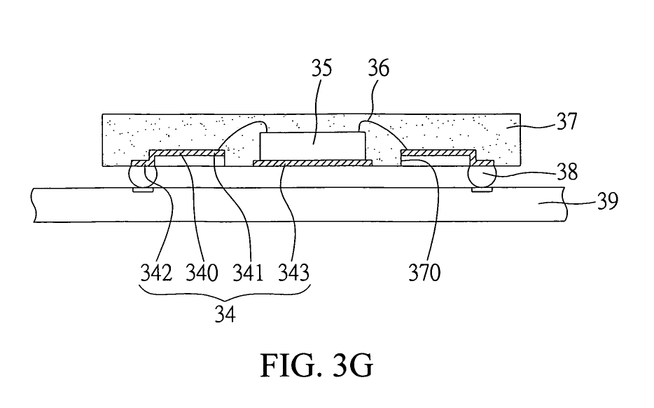

Referring to FIGS. 3A to 3F, a semiconductor package and a fabrication method thereof according to a first embodiment of the present invention is shown.

Referring to FIG. 3A, a carrier board 30 made of metal, such as a copper plate, is prepared. The carrier board 30 is covered by a first resist layer 31 having a plurality of first openings 310 for defining extension circuits that subsequently connect with a semiconductor chip.

Then, an electroplating process is performed to form metal bumps 32 in the first openings 310. The metal bumps 32 can be made of such as copper.

As shown in FIGS. 3B and 3C, wherein FIG. 3C is a corresponding top view of FIG. 3B, the first resist layer 31 is removed, and the carrier board 30 is covered by a second resist layer 33 having a plurality of second openings 330 that expose the metal bumps 32 and portions of the carrier board 30. As shown in FIG. 3C, the broken lines indicate the metal bumps. The second openings 330 are slightly smaller than or equal to the metal bumps 32 in width.

The second openings 330 define the extension circuits to be formed subsequently, bonding pads and extension pads to be formed on respective ends of the extension circuits, and a die pad for attaching a semiconductor chip.

As shown in FIG. 3D, an electroplating process is performed to form a metal layer 34 in the second openings 330. The metal layer 34 comprises extension circuits 340, bonding pads 341 and extension pads 342 formed on respective ends of the extension circuits 340, and a die pad 343 for attaching a semiconductor chip. The bonding pads 341 are relatively disposed on the inner ends of the extension circuits 340 for electrically connecting with a chip, whereas the extension pads 342 are relatively disposed on the outer ends of the extension circuits 340 for external electrical connection.

The metal layer 34 can be made of one of Au/Pd/Ni/Pd, Au/Ni/Au, and Au/Cu/Au.

The extension pads 342 are disposed directly on surface of the carrier board 30 and have a height difference with respect to the extension circuits 340.

As shown in FIG. 3E, the second resist layer 33 is removed. A semiconductor chip 35 is attached to the metal layer 34 at a position corresponding to the die pad 343. The chip 35 is electrically connected to the metal layer 34 at positions corresponding to the bonding pads 341 through bonding wires 36. Thereafter, an encapsulant 37 is formed on the carrier board 30 to enclose the chip 35 and the bonding wires 36.

The portion of the metal layer 34 for attaching the chip 35 can function to ground the chip 35 or conduct heat.

As shown in FIG. 3F, the carrier board 30 and the metal bumps 32 are removed by etching, so as to form grooves 370 defined by the previous metal bumps 32 on the surface of the encapsulant 37. The extension circuits 340 are located inside the grooves 370, while the extension pads 342 are exposed from the surface of the encapsulant 37. Thus, a semiconductor package of the present invention is obtained.

In FIG. 3G, the extension pads 342 exposed from the encapsulant 37 may be electrically connected to an external device 39 through a conductive material 38.

Alternatively, in the fabrication method of the present invention, the semiconductor chip can be directly placed on the carrier board, thus omitting the metal layer formed on the die pad position. Further, the chip can be connected to the bonding pads by the flip-chip technology.

By the above fabrication method, the present invention further discloses a semiconductor package, comprising: an encapsulant 37 with a plurality of grooves 370 formed on surface thereof; extension circuits 340 formed in the grooves 370, wherein bonding pads 341 are disposed on one end of the extension circuits 340 while extension pads 342 are disposed on the other end thereof, and the extension pads 342 are exposed from the encapsulant 37; and a semiconductor chip 35 enclosed in the encapsulant 37 and electrically connected to the bonding pads 341. The semiconductor chip 35 is electrically connected to the bonding pads 341 via flip-chip or wire bonding technique.

### Second Embodiment

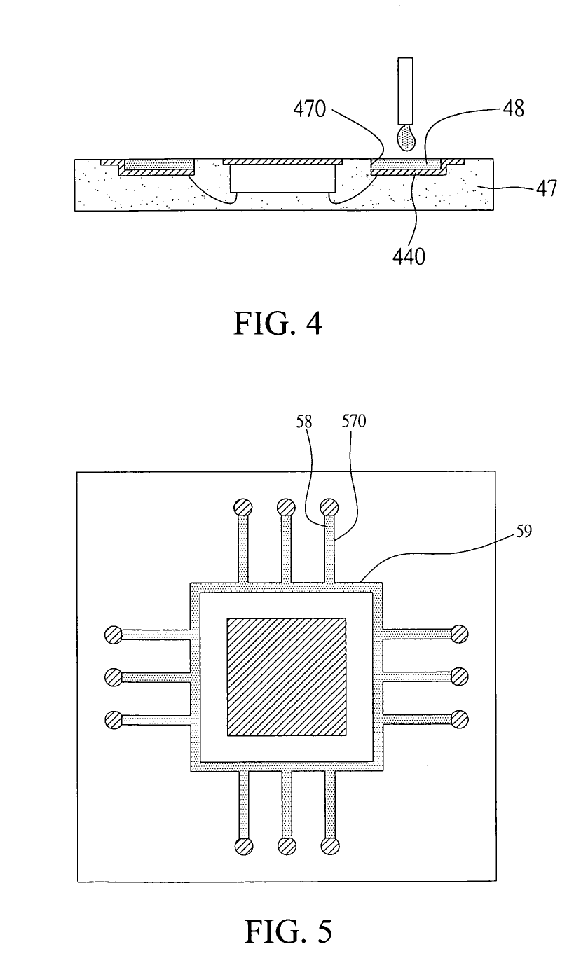

Referring to FIG. 4, a semiconductor package and a fabrication method thereof according to a second embodiment is shown.

The semiconductor package and the fabrication method of this embodiment are similar to those of the first embodiment. The main difference of the present embodiment from the first embodiment is that an insulating layer 48 is filled into the grooves 470 of the encapsulant 47 by such as dispensing so as to protect the extension circuits 440 inside the grooves 470 from exterior damage and contamination.

### Third Embodiment

Referring to FIG. 5, a bottom view of a semiconductor package and a fabrication method thereof according to a third embodiment of the present invention is shown.

The semiconductor package and the fabrication method of this embodiment are similar to those of the above embodiments. The main difference is that a guiding groove 59 is formed to connect the grooves 570 on the surface of the encapsulant 57, thereby facilitating filling of an insulating layer 58 in the grooves 570 and the guiding groove 59 by such as dispensing.

### Fourth Embodiment

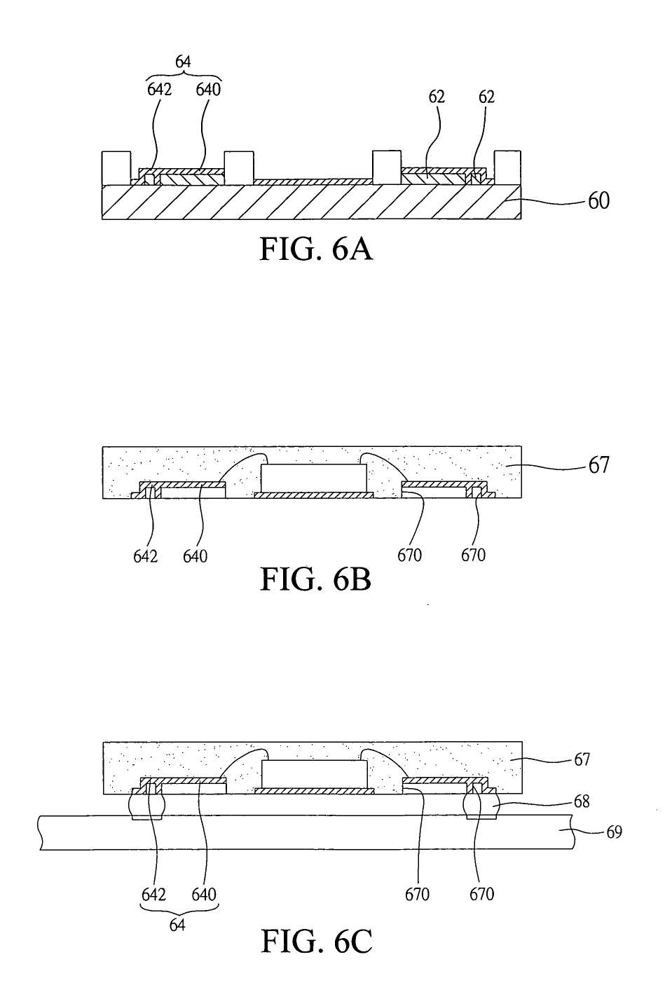

Referring to FIGS. 6A to 6C, a semiconductor package and a fabrication method thereof according to a fourth embodiment of the present invention is shown.

The semiconductor package and the fabrication method of this embodiment are similar to those of the above embodiments. The main difference is that metal bumps 62 are formed on the metal carrier board 60 not only at locations corresponding to the extension circuits 640, but also at locations corresponding to the extension pads 642. As a result, after process of electroplating the metal layer 64, chip mounting, package molding and removing the carrier board 60 and the metal bumps 62, a plurality of grooves 670 can be formed on the surface of the encapsulant 67 at locations corresponding to the extension circuits 640 and the extension pads 642, thereby increasing the contact area and bonding strength between the extension pads 642 and conductive material 68 for electrically connecting an external device 69.

### Fifth Embodiment

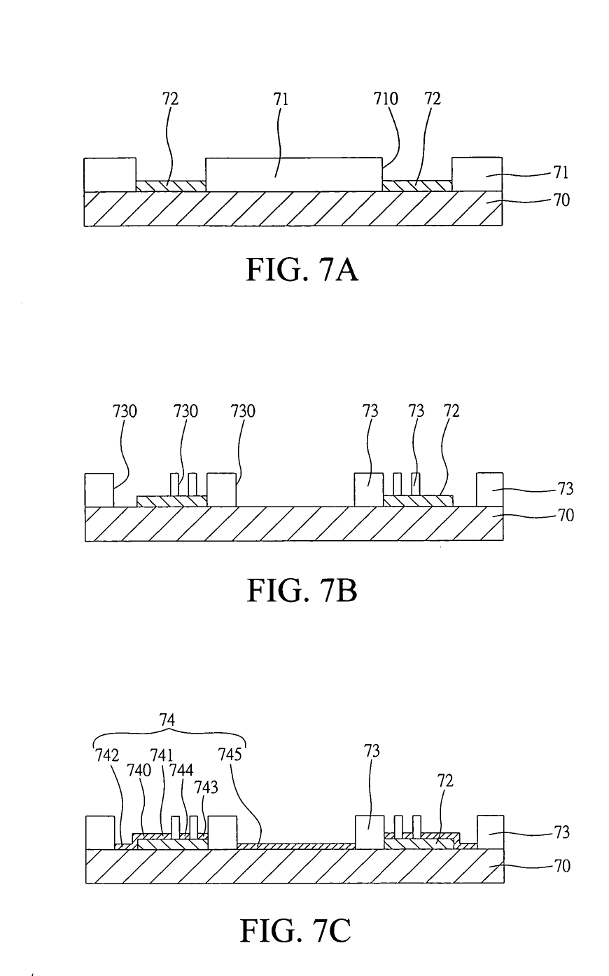

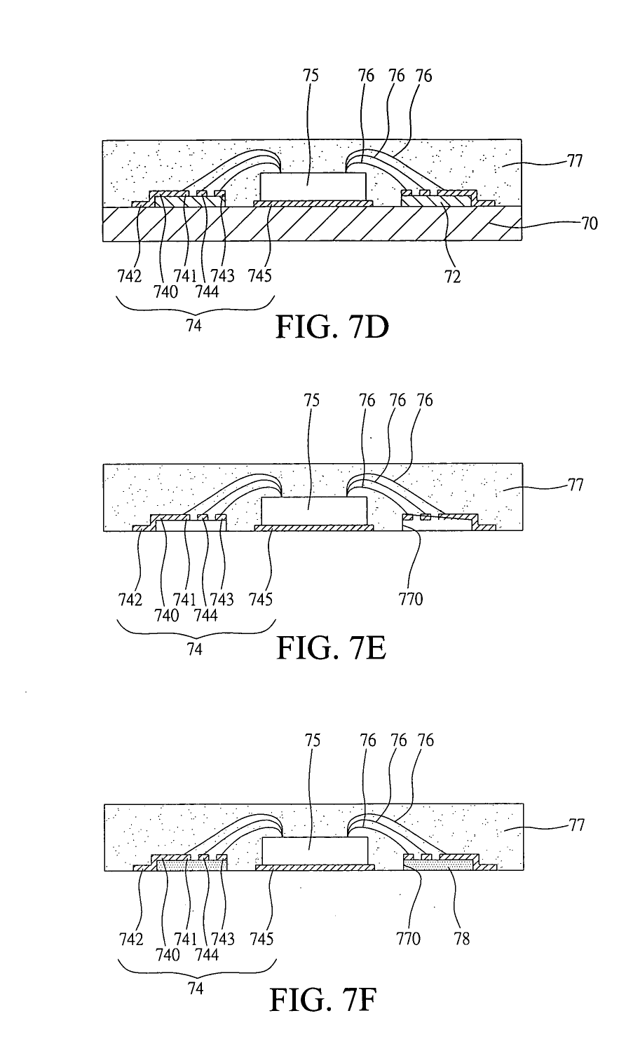

Referring to FIGS. 7A to 7F, a semiconductor package and a fabrication method thereof according to a fifth embodiment of the present invention is shown.

The semiconductor package and the fabrication method of this embodiment are similar to those of the above embodiments. The main difference is that ground and power circuits are formed in grooves of the encapsulant, thus improving electrical functionality of the package. Furthermore, the grooves are filled with an insulating layer to protect the ground and power circuits from short circuit.

As shown in FIG. 7A, a metal carrier board 70 is prepared, and surface of the metal carrier board 70 is covered with a first resist layer 71 having a plurality of openings 710. Then, metal bumps 72 are formed in the first openings 710 by electroplating. The metal bumps 72 are made of such as copper.

As shown in FIG. 7B, the first resist layer 71 is removed, and the metal carrier board 70 is covered with a second resist layer 73 having a plurality of openings 730 for exposing the metal bumps 72 and portions of the carrier board 70.

The second openings 730 are used for defining subsequently formed ground circuits, power circuits, extension circuits, bonding pads and extension pads on respective ends of the extension circuits, and a die pad for attaching the semiconductor chip.

As shown in FIG. 7C, an electroplating process is performed in order to form a metal layer 74 in the second openings 730. The metal layer 74 comprises ground circuits 743, power circuits 744, extension circuits 740, bonding pads 741 and extension pads 742 on respective ends of the extension circuits, and a die pad 745. The bonding pads 741 are relatively disposed on the inner ends of the extension circuits 740 for electrically connecting with the chip, whereas the extension pads 742 are relatively disposed on the outer ends of the extension circuits 740 for external electrical connection. The ground circuits 743 are ground rings or pads, for example. The power circuits 744 are power rings or pads, for example.

As shown in FIG. 7D, the second resist layer 73 is removed. A semiconductor chip 75 is attached to the metal layer 74 at a position corresponding to the die pad 745. The chip 75 is connected to the metal layer 74 at positions corresponding to the bonding pads 741, the ground circuits 743 and the power circuits 744 through bonding wires 76. An encapsulant 77 is provided on the metal carrier board 70 to enclose the chip 75 and the bonding wires 76.

As shown in FIG. 7E, the metal carrier board 70 and the metal bumps 72 are removed by etching, so as to form grooves 770 defined by previously removed metal bumps 72 on the surface of the encapsulant 77. As a result, the ground circuits 743, the power circuits 744 and the extension circuits 740 are formed in the grooves 770, while the extension pads 742 are exposed from the surface of the encapsulant 77.

As shown in FIG. 7F, the grooves 770 of the encapsulant 77 are filled with an insulating layer 78 to protect the ground circuits 743, the power circuits 744 and the extension circuits 740 from exterior contamination and damage as well as short circuit. Accordingly, the semiconductor package of the present invention is formed.

### Sixth Embodiment

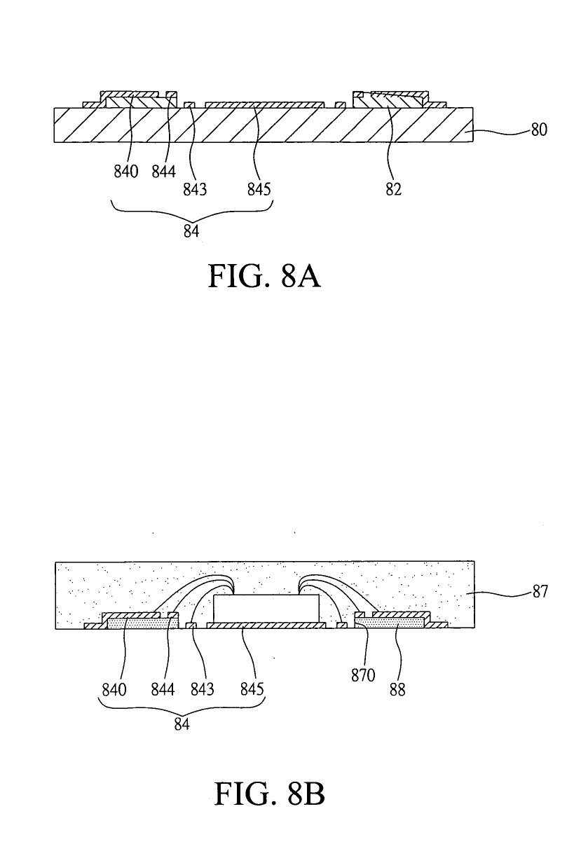

Referring to FIGS. 8A to 8B, a semiconductor package and a fabrication method thereof according to a sixth embodiment of the present invention is shown.

The semiconductor package and the fabrication method of this embodiment are similar to those of the above embodiments. The main difference is that the extension circuits 840 and the power circuits 844 are formed on the metal bumps 82, while the ground circuits 843 and the portion of the metal layer 84 used as a die pad are directly formed on the metal carrier board 80. As such, after die attachment, package molding and removal of the metal carrier board 80 and the metal bumps 82, the extension circuits 840 and the power circuits 844 are located in the grooves 870 of the encapsulant 87, the grooves 870 being filled with an insulating layer 88 to cover the extension circuits 840 and the power circuits 844, and the ground circuits 843 and the portion of the metal layer 84 used as the die pad 845 are exposed from the surface of the encapsulant 87 functioning as a ground face.

### Seventh Embodiment

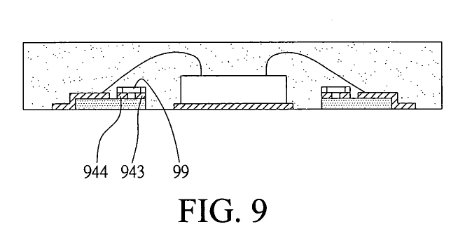

Referring to FIG. 9, a semiconductor package and a fabrication method thereof according to a seventh embodiment of the present invention is shown.

The semiconductor package and the fabrication method of this embodiment are similar to those of the above embodiments. The main difference is that a passive element 99 (e.g. capacitor) is provided on a ground circuit 943 and a power circuit 944 of the carrier-free semiconductor package of the present invention, so as to improve the electrical quality of the package.

Therefore, the method for fabricating the semiconductor package of the present invention essentially comprises: forming a plurality of metal bumps on a carrier board; forming on the carrier board and the metal bumps a metal layer having extension circuits and bonding pads and extension pads on respective ends of the extension circuits; electrically connecting at least one semiconductor chip to the bonding pads, forming on the carrier board an encapsulant to enclose the chip; removing the carrier board and the metal bumps to form a plurality of grooves on the surface of the encapsulant with the extension circuits located in the grooves, thereby allowing the extension pads of the extension circuits to be electrically connected with an external device through a conductive material.

As such, the semiconductor package of the present invention is free of a chip carrier, and the extension circuits can be disposed flexibly in accordance with the degree of integration of the chip and in proximity with the chip, thus effectively reducing the electric connection path between the chip and the extension circuits and improving circuit layout and electrical quality of the package. This eliminates problems such as short circuit and challenges in wire bonding associated with overly long bonding wires. Additionally, it reduces cost and complication related to the wire redistribution method, such as use of a dielectric layer to define terminals, sputtering, electroplating, exposure, developing and etching.

Furthermore, the present invention may further comprise forming metal bumps at positions where predefined ground and power circuits are to be formed, such that the ground and power circuits can be formed on the metal bumps for electrically connecting the semiconductor chip to the ground and power circuits. Moreover, passive elements such as capacitors can be disposed on the ground and power circuits, thus improving the electrical quality of the package. Thereafter, an encapsulant can be formed to enclose the chip and the carrier board and the metal bumps are removed to form a plurality of grooves on the surface of the encapsulant, such that the ground and power circuits are located within the grooves. The grooves are subsequently filled with an insulating layer to protect the exposed ground and power circuits from short circuit.

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A method for fabricating a semiconductor package, comprising:
providing a carrier board with a plurality of metal bumps formed thereon;
providing a resist layer on the carrier board, wherein the resist layer has openings to expose the metal bumps;
forming a metal layer in the openings of the resist layer, wherein the metal layer comprises extension circuits, and extension pads and bonding pads located on respective ends of the extension circuits;
removing the resist layer;
electrically connecting at least one semiconductor chip to the bonding pads;
forming an encapsulant on the carrier board to encapsulate the semiconductor chip; and
removing the carrier board and the metal bumps to form a plurality of grooves on a surface of the encapsulant for exposing the metal layer.

2. The method of claim 1, further comprises:
providing a first resist layer on the carrier board made of metal, and forming a plurality of first openings in the first resist layer;
forming the metal bumps in the first openings by electroplating;
removing the first resist layer;
providing a second resist layer on the carrier board, wherein the second resist layer has second openings for exposing the metal bumps and portions of the carrier board, and the second openings are smaller than or equal to the metal bumps in width;
forming the metal layer in the second openings by electroplating; and
removing the second resist layer.

3. The method of claim 1, wherein the bonding pads are disposed on inner ends of the extension circuits for electrically connecting to the semiconductor chip, while the extension pads are relatively disposed on outer ends of the extension circuits and exposed from the surface of the encapsulant for providing external electrical connection through a conductive material.

4. The method of claim 1, wherein the metal layer is made of one of Au/Pd/Ni/Pd, Au/Ni/Au, and Au/Cu/Au.

5. The method of claim 1, wherein the semiconductor chip is electrically connected to the bonding pads by one of wire bonding and a flip-chip technique.

6. The method of claim 1, wherein the metal layer further comprises a die pad for disposing the semiconductor chip and for the semiconductor chip to be grounded and heat-conducted.

7. The method of claim 1, wherein the semiconductor chip is disposed on one of the metal layer and the carrier board.

8. The method of claim 1, further comprises filling the grooves of the encapsulant with an insulating layer to cover the extension circuits, and exposing the extension pads.

9. The method of claim 8, wherein a guiding groove is formed on the surface of the encapsulant for interconnecting the grooves, and the grooves and the guiding groove are filled with the insulating layer.

10. The method of claim 1, wherein the metal bumps are further formed in position corresponding to the extension pads to form grooves corresponding to the extension pads in the encapsulant after the carrier board and the metal bumps are removed.

11. The method of claim 1, further comprising forming at least one ground circuit and at least one power circuit that allow the semiconductor chip to electrically connect to the ground circuit and the power circuit through bonding wires.

12. The method of claim 11, further comprises:
providing a first resist layer on the carrier board made of metal, and forming a plurality of first openings in the first resist layer to form the metal bumps in the first openings by electroplating;
removing the first resist layer and providing a second resist layer on the carrier board, wherein the second resist layer has second openings for exposing the metal bumps and portions of the carrier board;
forming the metal layer in the second openings by electroplating, wherein the metal layer comprises the ground circuit, the power circuit, the extension circuits, and the bonding pads and the extension pads located on respective ends of the extension circuits; and
removing the second resist layer.

13. The method of claim 11, wherein the ground circuit is one of a ground ring and a ground pad; and the power circuit is one of a power ring and a power pad.

14. The method of claim 11, wherein the ground circuit and the power circuit are exposed from the grooves of the encapsulant, and the grooves are filled with an insulating layer.

15. The method of claim 11, wherein the extension circuits and the power circuit are exposed from the grooves of the encapsulant and the grooves are filled with an insulating layer, while the ground circuit is exposed from the surface of the encapsulant.

16. The method of claim 11, wherein a passive element is disposed on the ground circuit and power circuit.

17. A semiconductor package, comprising:
an encapsulant formed with a plurality of grooves on a surface thereof;
extension circuits formed in the grooves, wherein bonding pads are disposed on one end of the extension circuits and extension pads are disposed on the other end of the extension circuits, and the extension pads are exposed from the encapsulant; and
a semiconductor chip encapsulated in the encapsulant and electrically connected to the bonding pads.

18. The semiconductor package of claim 17, wherein the bonding pads are disposed on inner ends of the extension circuits for electrically connecting to the semiconductor chip, while the extension pads are relatively disposed on outer ends of the extension circuits and exposed from the surface of the encapsulant for providing external electrical connection through a conductive material.

19. The semiconductor package of claim 17, wherein the extension circuits are made of one of Au/Pd/Ni/Pd, Au/Ni/Au, and Au/Cu/Au.

20. The semiconductor package of claim 17, wherein the semiconductor chip is electrically connected to the bonding pads by one of wire bonding and a flip-chip technique.

21. The semiconductor package of claim 17, wherein the grooves of the encapsulant are filled with an insulating layer to cover the extension circuits, and the extension pads are exposed.

22. The semiconductor package of claim 21, wherein a guiding groove is formed on the surface of the encapsulant for interconnecting the grooves, and the grooves and the guiding groove are filled with the insulating layer.

23. The semiconductor package of claim 17, wherein the encapsulant further has grooves corresponding to the extension pads in position.

24. The semiconductor package of claim 17, further comprises at least one ground circuit and at least one power circuit that allow the semiconductor chip to be electrically connected to the ground circuit and the power circuit through bonding wires.

25. The semiconductor package of claim 24, wherein the ground circuit is one of a ground ring and a ground pad, and the power circuit is one of a power ring and a power pad.

26. The semiconductor package of claim 24, wherein the ground circuit and the power circuit are exposed from the grooves of the encapsulant, and the grooves are filled with an insulating layer.

27. The semiconductor package of claim 24, wherein the extension circuits and the power circuit are exposed from the grooves of the encapsulant, the grooves are filled with an insulating layer, and the ground circuit is exposed from the surface of the encapsulant.

28. The semiconductor package of claim 24, wherein a passive element is disposed on the ground circuit and the power circuit.
